(19) United States
(12) Patent Application Publication
(10) Pub. No.: US 2008/0314117 A1
(43) Pub. Date: Dec. 25, 2008

(54) GAS SENSOR WITH IMPROVED SEALING STRUCTURE AND METHOD OF MANUFACTURING THE SAME

(75) Inventors: Yasuyuki Sato, Kasugai-city (JP); Yoshiaki Hirono, Takahama-shi (JP)

Correspondence Address: NIXON & VANDERHYE, PC, 901 NORTH GLEBE ROAD, 11TH FLOOR, ARLINGTON, VA, 22203, US

(73) Assignee: DENSO CORPORATION, Kariya-city (JP)

(21) Appl. No.: 12/143,113

(22) Filed: Jun. 20, 2008

(30) Foreign Application Priority Data
Jun. 22, 2007 (JP) 2007-165196

(51) Int. Cl. G01N 7/00; G01R 3/00

(52) U.S. Cl. 73/23.32; 29/595

(57) ABSTRACT

In a gas sensor, a seal member is filled in an annular space disposed between abutted inward and outward shoulder portions of a housing and a sensor member and an one open end of the housing. A tubular insulator is installed in the annular space to be mounted at its first end surface on the seal member. A ring member is installed in the annular space to be mounted at its first end surface on a second end surface of the tubular insulator. The one open end of the housing is configured to be inwardly crimped such that an edge of an inner circumference of the inwardly crimped one open end of the housing digs in a second end surface of the ring member to thereby fixedly press the seal member, the insulator, and the ring member to the abutted inward and outward shoulder portions.

### CROSS REFERENCE TO RELATED APPLICATIONS

This application is based on Japanese Patent Application No. 2007-165196 filed on Jun. 22, 2007. The descriptions of the Patent Application are all incorporated herein by reference.

### FIELD OF THE INVENTION

The present invention relates generally to gas sensors for measuring a specified component in gas, and methods of manufacturing the same. More particularly, the present invention relates to such gas sensors and manufacturing the same; these gas sensors are designed to measure the concentration of a specified gas component in exhaust gas of an internal combustion engine for motor vehicles. The concentration of a predetermined gas is directly related to the air-fuel ratio for each cylinder of the internal combustion engine.

### BACKGROUND OF THE INVENTION

In order to control an air-fuel ratio of an internal combustion engine for motor vehicles, a gas sensor is commonly disposed to measure the concentration of specified gas component, such as oxygen, in exhaust gas of the internal combustion engine.

Such a gas sensor is commonly equipped with a hollow tubular housing formed at its inner periphery with an inward tapered shoulder. The gas sensor is also equipped with a tubular sensor member disposed in the housing. The sensor member formed at its one end with a gas-sensing head and at its outer periphery with an outward tapered shoulder. The sensor member is arranged such that the outward tapered shoulder of the sensor member is in contact with the inward tapered shoulder of the housing.

The gas sensor is provided with a tubular air-exposed cover coupled to one end of the housing close to the other end of the sensor member to define a reference gas chamber therein into which reference gas, such as atmospheric air, can be introduced. The gas sensor is also provided with a measurement-gas exposed cover coupled to the other end of the housing to define a measurement gas chamber therein into which exhaust gas with oxygen can be entered.

The housing is also formed in its inner periphery with an annular recess located close to the contacted shoulders toward the other end of the housing. This results that an annular space is formed between the annular recess of the housing and the outer periphery of the sensor member.

Protect members are disposed in the annular space and designed to protect the sensor member.

The protect members include a tubular seal member and a tubular insulator. The seal member is partly filled in a shoulder-side end portion of the annular space close to the contacted shoulders, and the tubular insulator is partly filled in the annular space to be mounted at its one annular end surface on the seal member.

A metal ring is mounted at its one end surface on the other annular end surface of the tubular insulator.

The other end of the housing is crimped or curled inwardly to be in contact with the other end surface of the metal ring. This allows the crimped other end of the housing to press the seal member, tubular insulator, and metal ring toward the sensing-head of the sensor member. This ensures hermetical seal between the sensor member and the housing, making it possible to airtightly separate the measurement gas chamber and the reference gas chamber.

In recent yeas, the temperature of exhaust gas of automobile engines has increased in order to meet tightened legal requirements of emission control. This increases thermal loads on the seal member, causing the seal member to become less tight, in other words, shrink in size. This may reduce the air-tightness between the housing and the sensor member.

In order to address the shrinkage of the seal member in size, Japanese Patent Application Publication No. H10-10082 discloses an improved structure of such a gas sensor.

Referring to FIG. 12, the gas sensor 9 disclosed in the Japanese Patent Application Publication is equipped with a ring spring 95 disposed between one annular end surface of a tubular insulator 942 and a flange of a tubular air-exposed cover 944. The ring spring 95 works to urge the tubular insulator 942 and a seal member 941 toward the measurement-gas chamber side of a housing 92.

Specifically, the inwardly crimped end 922 of the housing 92 gives pressing force to the ring spring 95 via the flange of the air-exposed cover 944 and a metal gasket. The pressing force allows the inner peripheral portion of the ring spring 95 to press the tubular insulator 942 toward the measurement-gas chamber side of the housing 92.

With the structure of the gas sensor 9, even if the seal member 941 becomes less tight due to an increase in thermal loads acting thereon, elastic displacement of the ring spring 95 increases the load of the seal member 941 on the contact portion between the housing 92 and a sensor member 93. This aims at sealing against leakage of the exhaust gas between the housing 92 and the sensor member 93.

### SUMMARY OF THE INVENTION

However, in order to effectively apply the elastic displacement of the ring spring 95 on the seal member 941 so as to actually compensate for the reduction in the tightness of the seal member 941, additional means are required for:

reducing the thickness of the ring spring 95;

increasing the distance between the inner circumference and the outer circumference of the ring spring 95; and/or

reducing the Young's modulus of the ring spring 95.

However, the gas sensor 9 has size restraints required to ensure its installability in a limited space, such as a space in the exhaust system of motor vehicles. In addition, the gas sensor 9 is required to have high temperature endurance because it is usually used in a high temperature atmosphere, such as the exhaust gas of the internal combustion engine.

It may be therefore difficult to design gas sensors that have a high elastic-displacement characteristic sufficient to compensate for the reduction in the tightness of the seal member 941 while meeting the requirements therefor.

Thus, the inventors of this Patent Application have focused on another factor that may cause the reduction in the sealability between the housing and the sensor member.

Specifically, in a high-temperature environment, the housing radially expands away from the protect members due to the difference in linear expansion coefficient between the housing and each of the protect members. This causes the crimped end of the housing to outwardly move in a radial direction relative to the tubular insulator and the seal member.

The crimped end of the housing is therefore slidably moved on the other end surface of the metal ring from the inner circumference side of the tubular insulator to the outer circumferential side thereof. This reduces the pressing force based on the crimped end of the housing to the seal member. In other words, the movement of the crimped end of the housing reduces the load of the crimped end of the housing on the seal member, the tubular insulator, and the metal ring.

This therefore results in the reduction in the sealability between the housing and the sensor member.

In order to avoid the reduction in the sealability between the housing and sensor member due to the difference in linear expansion coefficient between the housing and each protect member, the material(s) of the housing and that of each protecting member can be determined to reduce the difference in linear expansion coefficient therebetween.

This approach however may be practically difficult because materials that can be employed in the housing and each of the protect members to be used in a high temperature circumstance are limited from standpoints of function, heat durability, and cost.

In view of the background, an object of at least one aspect of the present invention is to reduce the scalability between a housing and a sensor-member protect member of a gas sensor even if there is the difference in linear expansion between the housing and the sensor member protect member of the gas sensor.

The inventors of this Patent Application has completed the present invention described hereinafter so as to achieve the object.

Specifically, according to one aspect of the present invention, there is provided a gas sensor. The gas sensor includes a tubular housing having one open end and an inner circumference defining a lengthy opening, the inner circumference having an inward shoulder portion. The gas sensor includes a lengthy tubular sensor member having an outer circumference and working to sense at least a component of gas. The outer circumference has an outward shoulder portion. The sensor member is disposed in the lengthy opening such that the outward shoulder portion and the inward shoulder portion are in abutment with each other. The outer circumference of the sensor member and the inner circumference of the housing prove an annular space therebetween. The annular space is disposed between the abutted inward and outward shoulder portions and the one open end of the housing. The gas sensor includes a seal member filled in the annular space to be mounted on the abutted inward and outward shoulder portions, and a tubular insulator having a first end surface and a second end surface opposite thereto and installed in the annular space to be mounted at the first end surface thereof on the seal member. The gas sensor includes a ring member having a first end surface and a second end surface opposite thereto and installed in the annular space to be mounted at the first end surface thereof on the second end surface of the tubular insulator. The one open end of the housing is configured to be inwardly crimped such that an edge of the inner circumference of the inwardly crimped one open end of the housing digs in the second end surface of the ring member to thereby fixedly press the seal member, the insulator, and the ring member to the abutted inward and outward shoulder portions.

According to another aspect of the present invention, there is provided a method of manufacturing a gas sensor. The method includes preparing a tubular housing having one open end and an inner circumference. The inner circumference defines a lengthy opening and having an inward shoulder portion. The method includes preparing a lengthy tubular sensor member having an outer circumference and working to sense at least a component of gas. The outer circumference has an outward shoulder portion. The method includes inserting, from the one open end of the housing, the sensor member in the lengthy opening such that the outward shoulder portion and the inward shoulder portion are in abutment with each other. The outer circumference of the sensor member and the inner circumference of the housing provide an annular space therebetween. The annular space is disposed between the abutted inward and outward shoulder portions and the one open end of the housing. The method includes filling a seal member in the annular space to be mounted on the abutted inward and outward shoulder portions, and installing, in the annular spade, a tubular insulator to be mounted at one end surface thereof on the seal member. The method includes installing, in the annular space, a ring member to be mounted at one end surface thereof on an other end surface of the tubular insulator. The method includes inwardly crimping the one open end of the housing such that an edge of the inner circumference of the inwardly crimped one open end of the housing digs in an other end surface of the ring member to thereby fixedly press the seal member, the insulator, and the ring member to the abutted inward and outward shoulder portions.

### BRIEF DESCRIPTION OF THE DRAWINGS

Other objects and aspects of the invention will become apparent from the following description of embodiments with reference to the accompanying drawings in which:

FIG. 1 is a partially cross sectional view schematically illustrating an internal structure of a gas sensor according to a first embodiment of the present invention;

FIG. 2 is an enlarged longitudinal cross sectional view a portion of the gas sensor illustrated in FIG. 1;

FIG. 3 is an enlarged cross sectional view schematically illustrating a coupling structure between one end of a housing of the gas sensor and a metal ring thereof illustrated in FIG. 2;

FIG. 4 is an enlarged cross sectional view schematically illustrating a crimping process in a method of manufacturing the gas sensor according to the first embodiment;

FIG. 5 is an enlarged cross sectional view schematically illustrating a crimping process in a method of manufacturing the gas sensor according to the first embodiment;

FIG. 6A is an enlarged view schematically illustrating an angle of α by which an annular flat surface of a die is inwardly inclined with respect to a horizontal direction orthogonal to an axial direction of the die according to the first embodiment;

FIG. 6B is an enlarged view schematically illustrating an angle of α by which the annular flat surface of a die is parallel to the horizontal direction orthogonal to the axial direction of the die according to the first embodiment;

FIG. 6C is an enlarged view schematically illustrating an angle of α by which the annular flat surface of the die is outwardly inclined with respect to the horizontal direction orthogonal to the axial direction of the die according to the first embodiment;

FIG. 7 is an enlarged longitudinal cross sectional view a portion of a gas sensor according to a second embodiment of the present invention;

FIG. 8 is an enlarged longitudinal cross sectional view a portion of a gas sensor according to a third embodiment of the present invention;

FIG. 9 is a graph schematically illustrating an experiment result for demonstrating an effect of improvement of a sealability between the housing and a sensor member 3 of the gas sensor according to the first embodiment of the present invention;

FIG. 10 is a table schematically illustrating relationships between the hardness of the housing and that of the metal ring of each of test samples of the gas sensor according to the first embodiment and measured maximum depth of a corresponding one of the test samples thereof;

FIG. 11 is an enlarged cross sectional view schematically illustrating a coupling structure between one end of a housing and a metal ring of a gas sensor as a comparison example of the gas sensor according to the first embodiment of the present invention; and

FIG. 12 is an enlarged longitudinal cross sectional view a portion of a conventional gas sensor.

### DETAILED DESCRIPTION OF EMBODIMENTS OF THE INVENTION

Embodiment of the present invention will be described hereinafter with reference to the accompanying drawings.

### First Embodiment

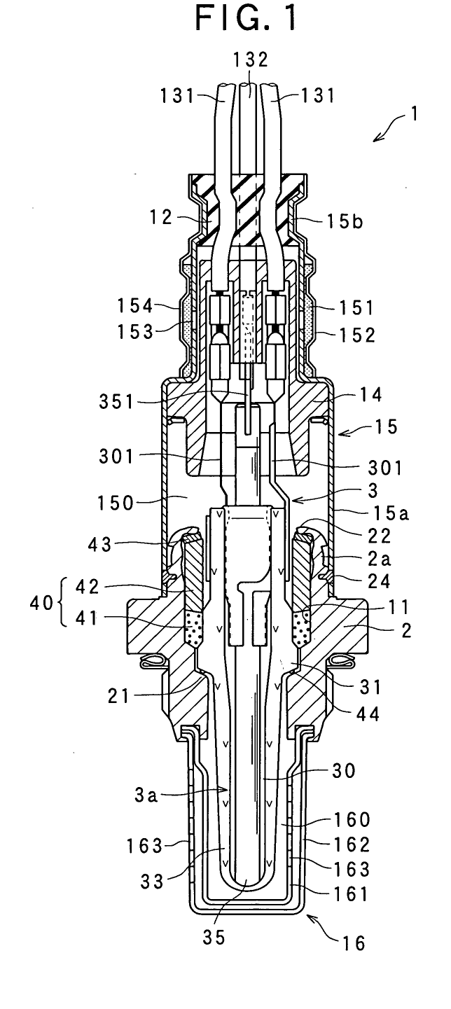

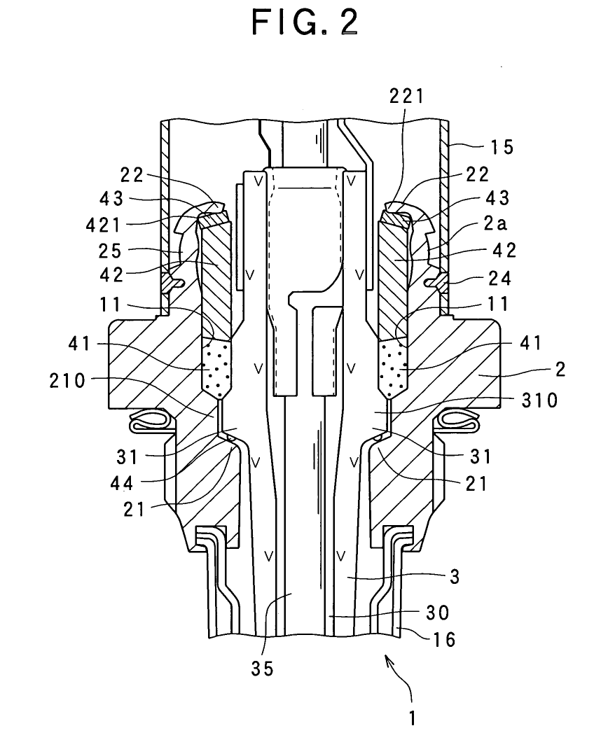

Referring to FIGS. 1 to 6C, wherein like reference numbers refer to like parts in several views, particularly to FIGS. 1 and 2, there is shown a gas sensor 1 according to the first embodiment of the present invention.

The gas sensor 1 is designed to be installed in, for example, an exhaust pipe of an internal combustion engine for motor vehicles to measure the concentration of a component, such as oxygen (O₂), nitrogen oxides (NOₓ), carbon dioxide (CO₂), or hydro carbon (HC) in exhaust gas of the internal combustion engine. The gas sensor is preferably used to control the air-fuel ratio for each cylinder of the internal combustion engine, detect the degree of catalysts for cleaning the exhaust gas, and the like.

The gas sensor 1 includes a lengthy sensor member 3 and a tubular housing 2 with a lengthy opening therethrough for supporting and protecting the sensor member 3. The gas sensor 1 also includes a tubular sleeve (cover) 15 and a tubular cover assembly 16. Each of the tubular housing 2, tubular sleeve 15, and tubular cover assembly 16 is made of, for example, stainless steel.

The tubular sleeve 15 has one open end. The tubular housing 2 is arranged to be fitted at its one open end portion 2a in the one open end of the tubular sleeve 15. This allows the lengthy opening of the housing 2 and an inner hollow portion of the tubular sleeve 15 to communicate with each other. The one open end portion 2a of the tubular housing 2 to be fitted in the one open end of the tubular sleeve 15 will be referred to as “mating portion 2a” hereinafter.

The tubular cover assembly 16 has one closed end and one open end opposite thereto; this open end of the tubular cover assembly 16 is fixedly joined to the other open end of the housing 2.

The tubular housing 2 is formed at its inner circumference with an inward shoulder 21 to be tapered toward the other open end thereof to provide a large diameter portion 210 extending from the inward shoulder 21 toward the one open end of the housing 2. The inward shoulder 21 and the large diameter portion 210 will be referred to simply as “inward shoulder portion 21” hereinafter.

The sensor member 3 consists of a tubular solid electrolyte body 33 having a closed end, an open end opposite thereto, and a substantially U-shape in its longitudinal cross section; this form of the solid electrolyte body 33 defines a hollow reference gas chamber 30 around the inner circumference of the tubular solid electrolyte body 33.

The solid electrolyte body 33 is composed of a sintered ceramic dioxide based on zirconium, and formed at its outer circumference with an outward shoulder 31 to be tapered toward the closed end thereof to provide a large diameter portion 310 extending from the outward shoulder 31 toward the one open end of the solid electrolyte body 3a. The outward shoulder 31 and the large diameter portion 310 will be referred to simply as “outward shoulder portion 31” hereinafter.

The sensor member 3 is disposed longitudinally in the housing 2 such that:

the closed end of the solid electrolyte body 3a projects from the other open end of the housing 2; and

the outward shoulder portion 31 of the solid electrolyte body 3a is in abutment with the inward shoulder portion 21 of the housing 2 via an annular metal gasket 44 so as to be partly laminated on the inward shoulder portion 21.

The annular metal gasket 44 is made of, for example, stainless steel to ensure a hermetical seal between the inward shoulder portion 21 and the outward shoulder portion 31.

The sensor member 3 also consists of a pair of gas-permeable electrodes (not shown). One of the pair of electrodes is mounted on a part of the outer circumference of the overhanging portion of the solid electrolyte body 33, and the other thereof is mounted on the opposing part of the outer circumference of the overhanging portion of the solid electrolyte body 33. The assembly of the solid electrolyte body 33 and the electrodes will be referred to as “sensing element 3a” hereinafter, and the overhanging portion of the sensor member 3 will be referred to as “sensor head” hereinafter.

The sensor member 3 includes a ceramic heater 35 composed of a sintered ceramic dioxide based on alumina in which a heating element made of platinum or the like is embedded. The heater 35 is disposed in the hollow reference-gas chamber 30 and operative to heat the sensing element 3 up to a desired activation temperature therefor.

The housing 2 is also formed in its inner circumference with an annular recess 11. The annular recess 11 is arranged to extend from the inward shoulder portion 21 up to an annular portion of the inner circumference at the one open end of the housing 2. This results that an annular space is formed between the annular recess 11 of the housing 2 and the outer periphery of the solid electrolyte body 33.

The tubular sleeve 15 consists of a first wall 15a and a second wall 15b. The first wall 15a has one open end and the other open end opposite thereto. In the one open end of the first wall 15a, the mating portion 2a of the housing 2 is fitted. The other open end of the first wall 15a is continuously coupled to one open end of the second tubular wall 15b such that the first wall 15a is greater in diameter than the second wall 15b. The structure serves the other open end of the first wall 15a as a shoulder portion.

The first wall 15a of the tubular sleeve 15 defines a reference gas chamber 150 therein so that the reference gas chamber 150 is arranged to communicate with an inner follow space of the second wall 15b and with the reference gas chamber 30 defined in the sensing element 3a.

The sensor member 3 includes a rubber bush 12 fitted in the other open end of the second wall 15b to close it.

The tubular cover assembly 16 is made up of an inner cover 161 and an outer cover 162. The inner cover 161 is mounted at its open end on the other open end of the housing 2 to surround the sensor head of the sensor member 3. The outer cover 162 is mounted at its open end on the other open end of the housing 2 to cover the inner cover 161. The inner and outer covers 161 and 162 define a measurement gas chamber 160 around the sensor head of the sensor member 3.

Each of the inner and outer covers 161 and 162 is formed with gas inlets 163 that allow entrance of gas being measured, such as the exhaust gas, into the measurement gas chamber 160. In other words, the structure of the tubular cover assembly 16 permits the sensor head of the sensor member 3 to be protected with the sensor head being exposed to the gas to be measured. The gas to be measured by the sensor member will be referred to as “measurement gas” hereinafter.

The sensor member 3 includes a pair of output lines 301 and a tubular porcelain insulator 14. The tubular porcelain insulator 14 is held in the shoulder portion of the first wall 15a. The output lines 301 are electrically connected to the pair of electrodes of the sensing element 3a, respectively. The output lines 301 are arranged to extend through the reference gas chamber 150 into an inner hollow portion of the porcelain insulator 14 to be retained thereby.

The sensor member 3 includes a pair of lead wires 131 one end portions of which are held in the porcelain insulator 14 and electrically connected to the pair of output lines 301, respectively. The lead wires 131 are arranged to penetrate through the rubber bush 12 to be drawn out from the tubular sleeve 15.

In addition, the sensor member 3 includes a pair of power supply lines 351 electrically connected to the heater 35 thereof, and arranged to extend from the first wall 15a into the second wail 15b.

The sensor member 3 includes a pair of lead wires 132 one end portions of which are held in the porcelain insulator 14 and electrically connected to the pair of power supply lines 301, respectively. The lead wires 132 are arranged to penetrate through the rubber bush 12 to be drawn out from the tubular sleeve IS.

The lead wires 131 and 132 are connected with a control circuit, such as an electronic control unit (ECU) (not shown).

The gas sensor 1 includes a cylindrical water-repellent filter 151 arranged to surround the outer circumference of the second wall 15b. The second wall 15b of the tubular sleeve 15 is formed with air inlets 153.

The gas sensor 1 includes a tubular filter cover 152 arranged to cover the outer circumference of the water-repellent filter 151 and that of the second wall 15b. The tubular filter cover 152 is formed with air inlets 154. The filter cover 152 is crimped inwardly at some points along a longitudinal direction thereof to affix the water-repellent filter 151 to the outer circumference of the second wall 15b together therewith.

The air inlets 153 and 154 allow air as reference gas to enter into the second wall 15b therethrough and through the water-repellent filter 151. The air entered in the second wall 15b passes through the inner follow space of the second wall 15b around the outer circumference of the porcelain insulator 14 to enter into the reference gas chamber 30.

Additionally, in the first embodiment, the gas sensor 1 includes protect members 40 disposed in the annular space and configured to protect the sensing element 3a of the sensor member 3.

The protect members 40 include a tubular seal member 41 and a tubular insulator 42. The seal member 41 is made of a powdery seal material, such as talc, and is filled in a shoulder-side end portion of the annular space close to the overlappedly contacted shoulder portions 21 and 31 in the longitudinal direction of the gas sensor 1. The tubular insulator 42 is made of, for example, alumina ceramic and partly filled in the annular space to be mounted at its one annular end surface on the seal member 41.

The tubular insulator 42 has the other annular end surface 421 to be outwardly tapered in its longitudinal direction.

The gas sensor 1 includes a sheet-shaped metal ring 43 made of, for example, stainless steel. The metal ring 43 has one end surface 43a and the other end surface 43b. The metal ring 43 is mounted at its one end surface 43a on the tapered end surface 421 of the insulator 42 so that the other end surface 43b is outwardly tapered in substantially parallel to the tapered surface 421 of the insulator 42.

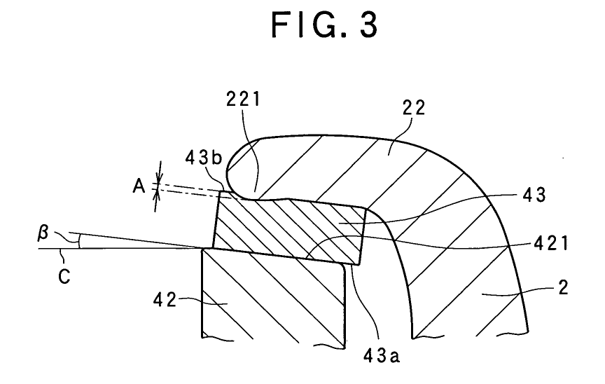

The periphery of the one open end of the housing 2 is rounded. Referring to FIG. 3, the one open end of the housing 2 is crimped or swaged inwardly toward the tapered end surface 43b of the metal ring 43 to provide an inwardly wrapped annular crimped portion 22 so that an edge 221 of the inner circumference of the inwardly wrapped annular crimped portion 22 digs into the tapered end surface 43b of the metal ring 43. The inwardly wrapped annular crimped portion 22 will be referred to simply as “crimped portion 22” hereinafter.

Specifically, before the edge 221 of the inner circumference of the crimped portion 22 is engaged into the tapered end surface 43b of the metal ring 43, the edge 221 of the inner circumference of the one open end of the housing 2 to be in abutment with the tapered end surface 43b is parallel thereto.

Preferably, the maximum depth A of the edge 221 of the inner circumference of the crimped portion 22 of the housing 2 digging in the tapered end surface 43b of the metal ring 43 is set to be equal to or greater than 0.01 mm, more preferably equal to or greater than 0.03 mm. Note that the maximum depth A of the edge 221 means the length between the tapered end surface 43b and a point of the edge 221; this point of the edge 221 is most separated from the tapered end surface 43b.

This allows the crimped portion 22 of the housing 2 to press the metal ring 43, the insulator 42, and the seal member 41 toward the contacted shoulder portions 21 and 31 laminated in the longitudinal direction of the gas sensor 1. This ensures hermetical seal between the sensor member 3 (outward shoulder portion 31) and the housing 2 (the inward shoulder portion 21), making it possible to airtightly separate the measurement gas chamber 30 and the reference gas chamber 150.

Additionally, at the one open end of the tubular sleeve 15 (the first wall 15a), an annular welded joint 24 is formed to fixedly couple the one open end of the first wall 15a and the mating portion 2a of the housing 2. The annular welded joint 24 is located radially opposing the insulator 42.

Next, sensing functions of the gas sensor 1 will be described hereinafter.

While exhaust gas discharged from the internal combustion engine flows through the exhaust pipe, at temperatures in excess of the activation temperature by the heater 35 activated by the control circuit, the zirconium dioxide electrolyte body 33 will conduct the oxygen ions. The gas sensor 1 is designed to be responsible very close to a lambda value of one. As one electrode of the sensing element 3a of the sensor 1 is open to a reference value of the atmospheric air in the reference gas chamber 150, a greater quantity of oxygen ions will be present on this side. Due to electrolyte action these ions permeate the electrode and migrate through the solid electrolyte body 33. This builds up a charge rather like a battery detected by the control circuit. The size of the charge is dependent on the concentration of oxygen in the exhaust gas. The control circuit works to control the air-fuel ratio for each cylinder of the internal combustion engine based on the amount of charge measured by the gas sensor 1.

Next, characteristic processes in a method of manufacturing the gas sensor 1 according to the first embodiment will be described hereinafter.

The characteristic processes of the gas-sensor manufacturing method according to the first embodiment mainly include a sensor-member inserting process, a seal-member filling process, an insulator mounting process, a metal-ring mounting process, and a crimping process.

First, in the sensor-member inserting process, the sensor member 3 consisting of the sensing element 3a with the outward shoulder portion 31, the heater 35, the output lines 301, the porcelain insulator 14, the 0 lead wires 131, and the bush 12 is prepared. In addition, the housing 2 having the inward shoulder portion 21 and the one open end before being crimped is prepared.

After the preparation, the sensor member 3 is inserted, from its sensor head side, into the housing 2 via its one open end side such that:

the sensing element 3a projects from the other open end of the housing 2; and

the outward shoulder portion 31 is in abutment with the inward shoulder portion 21 of the housing 2 via the metal gasket 44 so as to be laminated in the longitudinal direction of the housing 2 (sensor member 3).

Next, in the seal-member filling process, a predetermined amount of the seal member 41, such as talc, is filled into the annular space formed between the annular recess 11 of the housing 2 and the outer periphery of the solid electrolyte body 33 of the sensor member 3.

A press die is prepared. The seal member 41 filled in the annular space is pressed by the press die to be compressed, resulting in increasing the density of the seal member 41.

Thereafter, in the insulator mounting process, the tubular insulator 42 having the outwardly tapered end surface 421 is mounted at its end surface opposing the tapered end surface 421 on the seal member 41 filled in the annular space.

Next, in the metal-ring mounting process, the sheet-shaped metal ring 43 having one and the other parallel end surfaces 43a and 43b is mounted at its one end surface 43a on the tapered end surface 421 of the insulator 42. This results that the other end surface 43b is outwardly tapered in substantially parallel to the tapered surface 421 of the insulator 42.

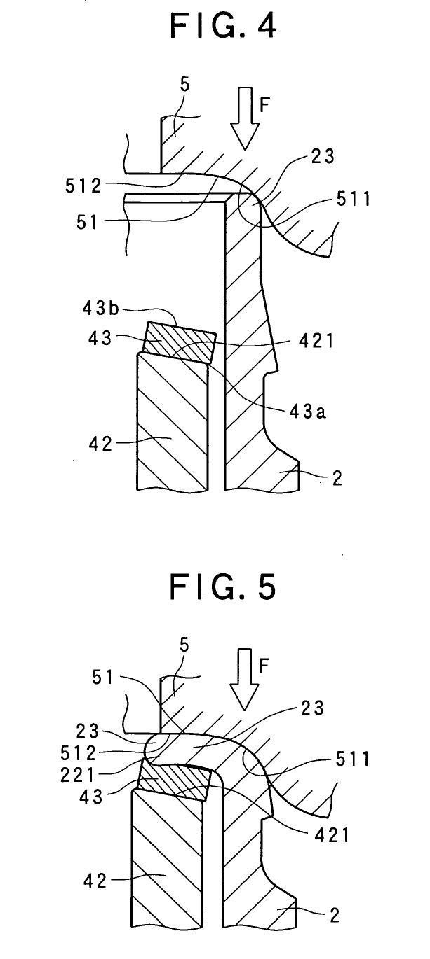

After the metal-ring mounting process, in the crimping process, referring to FIGS. 4 and 5, a swaging tool is prepared. For example, the swaging tool is equipped with a die 5 having a die surface 51. The die surface 51 consists of an annular fiat surface 512 and an outwardly flared surface 511 radially extending from the outer peripheral part of the annular flat surface 512. The outwardly flared surface 511 has a curved shape in its axial cross section.

The die 5 is arranged such that:

the axial direction of the die 5 is parallel to the longitudinal direction of the housing 2; and

the outwardly flared surface 511 is located to be in contact with a rounded outer corner of the one open end (see reference numeral “23” in FIG. 4) of the housing 2.

Thereafter, the swaging tool works to move the die 5 toward the other open end 23 of the housing 2 in a direction indicated by an arrow F to press the one open end 23 of the housing 2 theretoward. This deforms the one open end 23 of the housing 2 such that the one open end 23 of the housing 2 is inwardly bent along the outwardly flared surface 511 of the die 5, thus forming the crimped portion 22 (see FIG. 5).

When the inner circumference of the crimped portion 22 is in contact with the tapered end surface 43b of the metal ring 43, the one open end 23 of the housing 2 is further pressed by the die surface 51 of the die 5 toward the other end of the housing 2 until the edge 221 of the inner circumference of the crimped portion 22 digs into the tapered end surface 43b of the metal ring 43. This allows the crimped portion 22 to retain the seal member 41, the insulator 42, and the metal ring 43 on the contacted shoulder portions 21 and 31 while applying pressing force to them toward the contacted shoulder portions 21 and 31.

Specifically, in the first embodiment, the die surface 51 of the die 5 is designed such that:

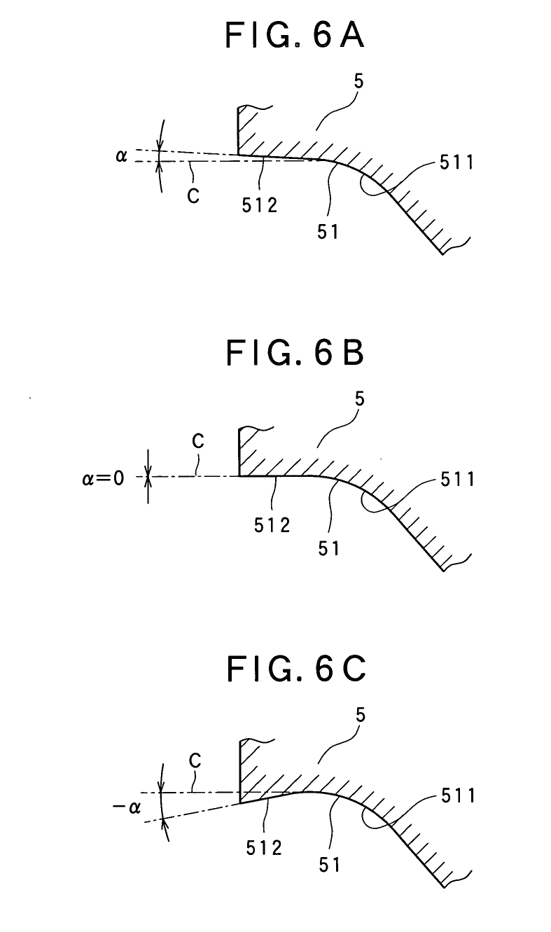

the annular fiat surface 512 is inwardly or outwardly inclined with respect to a horizontal direction C orthogonal to the axial direction of the die 5 by an angle of α (see FIGS. 6A to 6C); and

the angle α is smaller than a positive angle of β; this positive angle β represents the angle the tapered end surface 421 of the insulator 42 makes with respect to a radial direction of the gas sensor 1 (see FIG. 3). The sign of the angle α is positive when the annular flat surface 512 is inwardly inclined with respect to the horizontal direction C away from the outwardly flared surface 511 (see FIG. 6A). The angle α is zero when the annular flat surface 512 is in parallel to the horizontal direction C (see FIG. 6B). The sign of the angle α is negative when the annular flat surface 512 is outwardly inclined with respect to the horizontal direction C to be close to the outwardly flared surface 511 (see FIG. 6C).

More specifically, in the first embodiment, the crimping process includes a first crimping step and a second crimping step. In the first crimping step, the one open end 23 of the housing 2 is pressed in the longitudinal direction thereof to be inwardly bent at ambient temperature.

Next, in the second crimping step, the one open end 23 of the housing 2 is energized to be heated and softened while being pressed toward the other open end of the housing 2 so that the one open end 23 of the housing 2 is buckled to partly dig into the tapered end surface 43b of the metal ring 43. In the first embodiment, the same die 5 is used in the first and second crimping steps.

An example of each of the first and second crimping steps will be described hereinafter.

As described above, after the metal-ring mounting process, in the first crimping step, the die 5 is coaxially arranged over the one open end 23 of the housing 2 such that the outwardly flared surface 511 is located to be in contact with the rounded outer corner of the one open end 23 of the housing 2 (see FIG. 4).

Thereafter, the one open end 23 of the housing 2 is pressed toward the other open end thereof in the direction indicated by the arrow F by the die 5 so that the one open end 23 of the housing 2 is inwardly bent along the outwardly flared surface 511 of the die 5. This forms the crimped portion 22 to wrap on the metal ring 43 (see FIG. 5). The crimped portion 22 covered on the metal ring 43 applies pressing force to the laminated members 41, 42, and 43 mounted on the contacted shoulder portions 21 and 31 via the metal gasket 44 toward the contacted shoulder portions 21 and 31. This allows the outward shoulder portion 31 of the sensor member 3 to be pressed on the inward shoulder portion 21 of the housing 2 via the metal gasket 44.

Thereafter, in the second crimping step, the one open end 23 of the housing 2 is energized to be heated and softened while being pressed toward the other open end of the housing 2 by the die surface 51 of the die 5. This buckles the one open end 23 of the housing 2 so that the edge 221 of the inner circumference of the crimped portion 22 digs into the tapered end surface 43b of the metal ring 43. This results in more increasing the pressing force applied by the crimped portion 22 to the laminated members 41, 42, and 43 mounted on the contacted shoulder portions 21 and 31 via the metal gasket 44 in the lamination direction. This allows the outward shoulder portion 31 of the sensor member 3 to be more tightly pressed on the inward shoulder portion 21 of the housing 2 via the metal gasket 44.

After the second crimping step, the crimped portion 22 of the one open end of the housing 2 applies high stress to the laminated members 41, 42, and 43 mounted on the contacted shoulder portions 21 and 31 via the metal gasket 44 in the lamination direction. This makes the outward shoulder portion 31 of the sensor member 3 closely contact with the inward shoulder portion 21 of the housing 2.

Note that, in one of the first and second crimping steps, an alternative die except for the die 5 meeting the condition in that the angle β is greater than the angle α can be used. For example, only in the second crimping step, the die 5 meeting the condition in that the angle β is greater than the angle α can be used, and only in the first crimping step, the die 5 meeting the condition in that the angle β is greater than the angle α can be used. In the second crimping step, an alternative die having a die surface configured to allow press of the edge 221 of the inner circumference of the crimped portion 22 toward the other open end of the housing 2 need be used.

Effects of the gas sensor 1 according to the first embodiment will be described hereinafter.

The gas sensor 1 is configured such that the edge 221 of the inner circumference of the crimped portion 22 toward the other open end of the housing 2 is pressed to dig into the other end surface 43b of the metal ring 43. The load of the crimped portion 22 on the metal ring 43 mainly acts on the inner circumference side of the metal ring 43 in which the crimped portion 22 digs.

This stably forms a point of application of the load of the crimped portion 22 on the metal ring 43 at the inner circumference side thereof; this point is very close to the sensor member 3. This reduces the amount of the slide movement of the metal ring 43 at the point of application of the load of the crimped portion 22 relative to the insulator 42 due to the difference in linear expansion coefficient between the housing 2 and each of the protect members 41 and 42.

Thus, even in a high-temperature environment, the outward movement of the crimped portion 22 of the one open end of the housing 2 and the metal ring 43 at the point of application of the load of the crimped portion 22 is reduced, thus preventing the reduction in the pressing force applied to the seal member 41. This makes it possible to prevent reduction in the sealability between the housing 2 and the sensor member 3.

In addition, the maximum depth A of the edge 221 of the inner circumference of the crimped portion 22 of the housing 2 digging in the tapered end surface 43b of the metal ring 43 is set to be equal to or greater than 0.01 mm. This allows the point of application of the load of the crimped portion 22 on the metal ring 43 to be stably formed at the inner circumference side thereof, thus effectively preventing reduction in the sealability between the housing 2 and the sensor member 3. Preferably, the maximum depth A of the edge 221 of the inner circumference of the crimped portion 22 of the housing 2 digging in the tapered end surface 43b of the metal ring 43 can be set to be equal to or greater than 0.03 mm. This more effectively avoids reduction in the airtightness between the housing 2 and the sensor member 3.

In the first embodiment, because the other end surface 421 of the tubular insulator 42 is outwardly tapered in its longitudinal direction (axial direction), the other end surface 43b of the metal ring 43 is outwardly tapered in parallel to the tapered end surface 421 of the tubular insulator 42. This allows an inner periphery of the other end surface 43b to rise toward the one open end side of the housing 2.

Thus, when the one open end of the housing 2 is pressed to be inwardly bent to form the crimped portion 22, it is possible to easily make the edge 221 of the inner circumference of the crimped portion 22 dig into the rising inner periphery of the other end surface 43b of the metal ring 43. This makes it possible to easily provide the crimped portion 22 of the one end of the housing 2 digging in the tapered end surface 43b of the metal ring 43.

More particularly, in the first crimping step, the die 5 is coaxially arranged over the one open end 23 of the housing 2 such that:

the angle α the annular flat surface 512 makes with respect to a radial direction of the housing 2 is smaller than the angle β the tapered end surface 421 of the insulator 42 makes with respect to a radial direction of the housing 2; and

the outwardly flared surface 511 is located to be in contact with the rounded outer corner of the one open end 23 of the housing 2 (see FIG. 4).

This allows, when the one open end of the housing 2 is pressed to be inwardly bent to form the crimped portion 22, the edge 221 of the inner circumference of the crimped portion 22 to easily dig into the tapered end surface 43b of the metal ring 43. This makes it possible to easily provide the crimped portion 22 of the one end of the housing 2 digging in the tapered end surface 43b of the metal ring 43.

### Second Embodiment

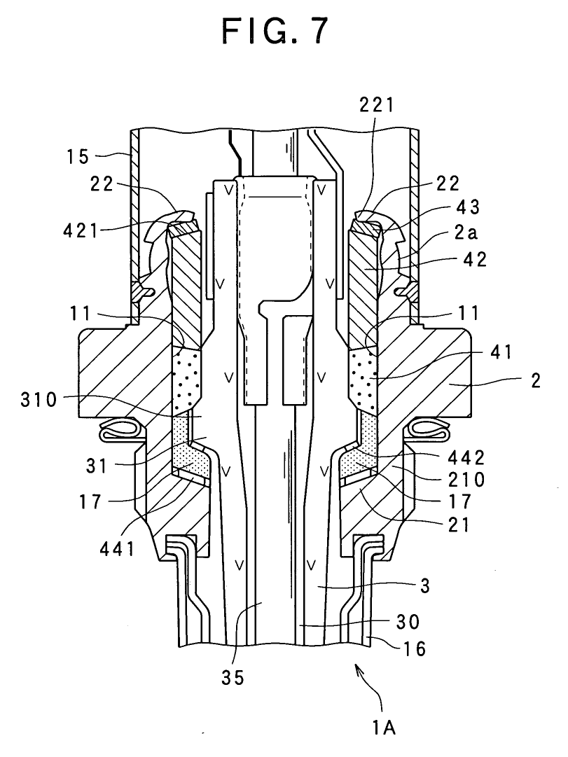

Referring to FIG. 7, there is illustrated a gas sensor 1A according to the second embodiment of the present invention. The structure of the gas sensor 1A according to the second embodiment is substantially identical to that of the gas sensor 1 according to the first embodiment except for some points described hereinafter. So, like parts between the gas sensors 1 and 1A according to the first and second embodiments, to which like reference characters are assigned, are omitted or simplified in description.

The gas sensor 1A further includes an annular insulator 17, a first annular metal gasket 441, and a second annular metal gasket 442.

The annular insulator 17 is disposed between the inward shoulder 21 of the housing 2 and the outward shoulder 31 of the solid electrolyte body 33 such that:

the inward shoulder 21 of the housing 2 is in abutment with the outer circumference of the annular insulator 17 via the first annular metal gasket 441.

Specifically, the sensor member 3 is disposed longitudinally in the housing 2 such that:

the closed end of the solid electrolyte body 33 projects from the other open end of the housing 2; and

the outward shoulder 31 of the solid electrolyte body 33 is in abutment with the inner circumference of the annular insulator 17 via the second annular metal gasket 442.

In the second embodiment, the inward shoulder 21, the large diameter portion 210, and the annular insulator 17 mean the inward shoulder portion 21.

The annular recess 11 is arranged to extend from the large diameter portion 210 of the inward shoulder portion 21 up to an annular portion of the inner circumference at the one open end of the housing 2. This results that an annular space is formed between the annular recess 11 of the housing 2, the annular insulator 17, and the outer periphery of the solid electrolyte body 33.

The protect members 40 include the tubular seal member 41 and the tubular insulator 42. The seal member 41 is filled in an insulator-side end portion of the annular space close to the annular insulator 17. The tubular insulator 42 is mounted at its one annular end surface on the seal member 41.

The tubular insulator 42 has the other annular end surface 421 to be outwardly tapered in its longitudinal direction.

The metal ring 43 is mounted at its one end surface 43a on the tapered end surface 421 of the insulator 42 so that the other end surface 43b is outwardly tapered in substantially parallel to the tapered surface 421 of the insulator 42 (see FIG. 3).

The one open end of the housing 2 is crimped or swaged inwardly toward the tapered end surface 43b of the metal ring 43 to provide the crimped portion 22 so that the edge 221 of the inner circumference of the inwardly wrapped annular crimped portion 22 digs into the tapered end surface 43b of the metal ring 43.

Like the first embodiment, the gas sensor 1A is configured such that the edge 221 of the inner circumference of the crimped portion 22 toward the other open end of the housing 2 is pressed to dig into the other end surface 43b of the metal ring 43. The load of the crimped portion 22 on the metal ring 43 mainly acts on the inner circumference side of the metal ring 43 in which the crimped portion 22 digs.

This forms stably a point of application of the load of the crimped portion 22 on the metal ring 43 at the inner periphery thereof; this point is very close to the sensor member 3 to thereby reduce the amount of the slide movement of the metal ring 43 at the point of application of the load of the crimped portion 22 relative to the insulator 42 due to the difference in linear expansion coefficient between the housing 2 and each of the members 17, 41 and 42 for protecting the sensor member 3.

Thus, even in a high-temperature environment, the outward movement of the crimped portion 22 of the one open end of the housing 2 and the metal ring 43 at the point of application of the load is reduced, thus preventing the reduction in the pressing force applied to the seal member 41 and the annular insulator 17. This makes it possible to prevent reduction in the sealability between the housing 2 and the sensor member 3.

Other effects achieved by the gas sensor 1 can also be achieved by the gas sensor 1A.

### Third Embodiment

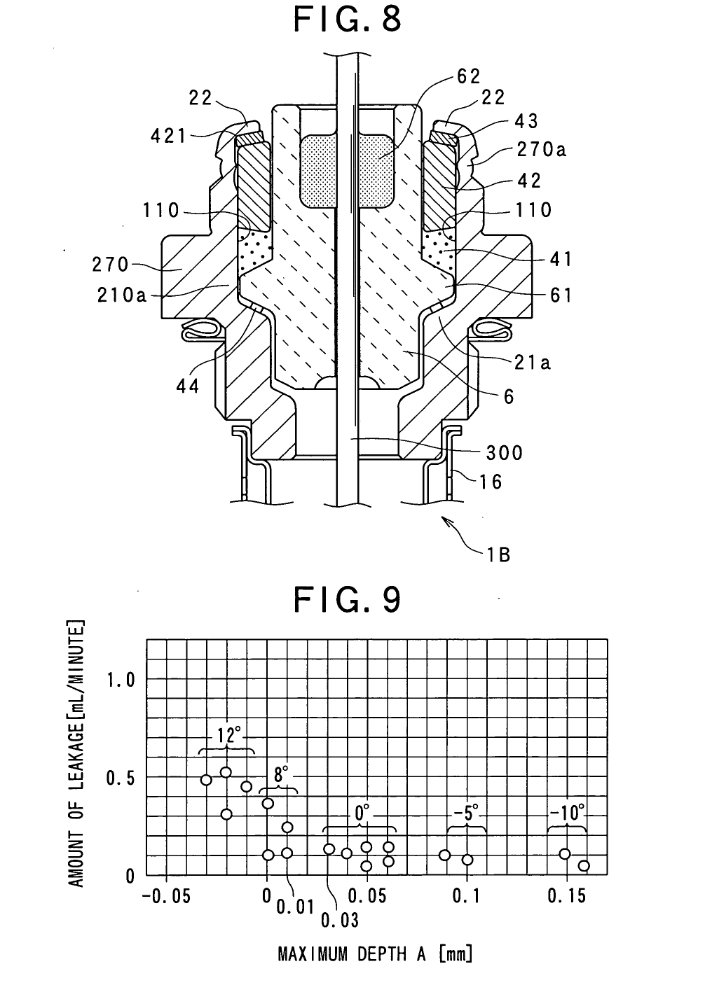

Referring to FIG. 8, there is shown a gas sensor 1B according to a third embodiment of the present invention. Like parts between the gas sensors 1 and 1B according to the first and third embodiments, to which like reference characters are assigned, are omitted or simplified in description.

The gas sensor 1B includes a lengthy sensor member 250 and a tubular housing 270 with a lengthy opening therethrough for supporting and protecting the sensor member 250.

The tubular housing 270 has one open end portion (mating portion) 270a to be fitted in the one open end of the tubular sleeve 15 (not shown), and the other open end fixedly joined to the one open end of the tubular cover assembly 16.

The tubular housing 270 is also formed at its inner circumference with an inward shoulder 21a to be tapered toward the other open end thereof to provide a large diameter portion 210a extending from the inward shoulder 21a toward the one open end of the housing 2. The inward shoulder 21a and the large diameter portion 210a will be referred to simply as “inward shoulder portion 21a hereinafter.

The sensor member 250 includes a stacked sensing element 300. The stacked sensing element 300 consists of a plurality of laminated ceramic seats in each thickness direction to form a bar shape. The sensor member 250 also includes a lengthy tubular insulator holder 6 through which the sensing element 300 is penetrated in a longitudinal direction of the insulator holder 6. The insulator holder 6 is formed at its one end contained in the one open end of the tubular sleeve 15 with a space 6a around a portion of the sensing element 300 located in the space 6a.

The sensor member 250 includes a glass member 62 sealed in part of the space 6a of the insulator holder 6.

The insulator holder 6 is formed at its outer circumference with an outward shoulder portion (outward stepped portion) 61.

The sensor member 250 is disposed longitudinally in the housing 270 such that:

one end and the other end of the sensing element 300 project from the one open end and the other open end of the housing 270, respectively; and

the outward shoulder portion 61 of the insulator holder 6 is in abutment with the inward shoulder portion 21a of the housing 270 via the annular metal gasket 44.

The protect members 40 include the tubular seal member 41 and the tubular insulator 42. The seal member 41 is filled in a shoulder-side end portion of the annular space close to the contacted shoulder portions 21a and 61. The tubular insulator 42 is mounted at its one annular end surface on the seal member 41.

The tubular insulator 42 has the other annular end surface 421 to be outwardly tapered in its longitudinal direction.

The metal ring 43 is mounted at its one end surface 43a on the tapered end surface 421 of the insulator 42 so that the other end surface 43b is outwardly tapered in substantially parallel to the tapered surface 421 of the insulator 42 (see FIG. 3).

The one open end of the housing 270 is crimped or swaged inwardly toward the tapered end surface 43b of the metal ring 43 to provide the crimped portion 22 so that the edge 221 of the inner circumference of the inwardly wrapped annular crimped portion 22 digs into the tapered end surface 43b of the metal ring 43.

Like the first embodiment, the gas sensor 1B is configured such that the edge 221 of the inner circumference of the crimped portion 22 toward the other open end of the housing 270 is pressed to dig into the other end surface 43b of the metal ring 43. The load of the crimped portion 22 on the metal ring 43 mainly acts on the inner periphery of the metal ring 43 in which the crimped portion 22 digs.

This forms stably a point of application of the load of the crimped portion 22 on the metal ring 43 at the inner periphery thereof; this point is very close to the sensor member 250 to thereby reduce the amount of the slide movement of the metal ring 43 at the point of application of the load of the crimped portion 22 relative to the insulator 42 due to the difference in linear expansion coefficient between the housing 270 and each of the members 41 and 42 for protecting the sensor member 250.

Thus, even in a high-temperature environment, the outward movement of the crimped portion 22 of the one open end of the housing 270 and the metal ring 43 at the point of application of the load is reduced, thus preventing the reduction in the pressing force applied to the seal member 41. This makes it possible to prevent reduction in the sealability between the housing 270 and the insulator 6 of the sensor member 250.

Other effects achieved by the gas sensor 1 can also be achieved by the gas sensor 1B.

FIG. 9 schematically illustrates an experiment result for demonstrating the effect of improvement of the sealability between the housing 2 and the sensor member 3 of the gas sensor 1 according to the first embodiment.

First, first to fifth test samples of the gas sensor 1 each with the crimped portion 22 different in shape from another one of the crimped portions 22 were prepared.

Specifically, the first to five test samples of the die 5 for the respective first to fifth test samples of the gas sensor 1 were prepared.

The first test sample of the die 5 has the annular flat surface 512 inwardly inclined with respect to the horizontal direction C orthogonal to the axial direction of the first test sample by an angle α of 12 degrees.

The second test sample of the die 5 has the annular flat surface 512 inwardly inclined with respect to the horizontal direction C orthogonal to the axial direction of the second test sample by an angle α of 8 degrees.

The third test sample of the die 5 has the annular flat surface 512 inclined to the horizontal direction C orthogonal to the axial direction of the third test sample by an angle α of 0 degrees.

The fourth test sample of the die 5 has the annular flat surface 512 outwardly inclined with respect to the horizontal direction C orthogonal to the axial direction of the fourth test sample by an angle α of −5 degrees.

The fifth test sample of the die 5 has the annular flat surface 512 outwardly inclined with respect to the horizontal direction C orthogonal to the axial direction of the fifth test sample by an angle α of −10 degrees.

The crimped portions of the first, second, third, fourth, and fifth test samples of the gas sensor 1 were manufactured using the first, second, third, fourth, and fifth test samples of the die 5, respectively, in the same manner as described in the first embodiment using the first and second crimping steps. In the first and second crimping steps for forming the crimped portion 22 of each of the first to fourth test samples of the gas sensor 1, the corresponding same test sample of the die 5 was used.

Note that, in forming the crimped portion 22 of each of the first to fifth test samples of the gas sensor 1, the load on the crimped portion 22 by the corresponding test sample of the die 5 was set to 1 ton in order to effectively demonstrate the differences between each of the first to fifth test samples of the gas sensor 1 and another one thereof. In order to actually manufacture the gas sensor 1 according to the first embodiment, the load on the crimped portion 22 by the corresponding test sample of the die 5 is preferably set to equal to or greater 3 ton.

Note that, in forming the crimped portion 22 of each of the first to fourth test samples of the gas sensor 1, the angle β the tapered end surface 421 of the insulator 42 makes with respect to a radial direction of the housing 2 is equally set to 10 degrees.

The first to fifth test samples of the gas sensor 1 manufactured by the first to fifth test samples of the die 5, respectively, were left in an oven at 700° C. for 300 hours individually or together. Thereafter, for example, five same closed containers were prepared, and each of the first to fifth test samples of the gas sensor 1 was installed in a corresponding one of the closed containers. The closed containers in which the first to fifth test samples of the gas sensor 1 are installed were heated until the temperature of the housing 2 of each of the first to fifth test samples of the gas sensor 1 reaches 650° C., and air at 5 atmospheres was applied in each of the closed containers. At that time, the amount of air to leak from gaps between the housing 2 and the sensor member 3 of each of the first to fifth test samples of the gas sensor 1 was individually measured.

After the measurement of the amount of leaking air, the maximum depth A of the edge 221 of the inner circumference of the crimped portion 22 of the housing 2 digging in the tapered end surface 43b of the metal ring 43 of each of the first to fifth test samples of the gas sensor 1 was individually measured by, for example, cross-section observation.

FIG. 9 illustrates relationships between the measured amounts of leaking air from the first to fifth test samples of the gas sensor 1 and the corresponding measured maximum depths A of the first to fifth test samples of the gas sensor 1. In FIG. 9, “12°” corresponding to the angle of α of 12 degrees represents the relationships between the measured amounts of leaking air from the first test samples of the gas sensor 1 and the corresponding measured maximum depths A of the first test samples thereof. “8°” corresponding to the angle of α of 8 degrees represents the relationships between the measured amounts of leaking air from the second test samples of the gas sensor 1 and the corresponding measured maximum depths A of the second test samples thereof.

“0°” corresponding to the angle of α of 0 degrees represents the relationships between the measured amounts of leaking air from the third test samples of the gas sensor 1 and the corresponding measured maximum depths A of the third test samples thereof, “−5°” corresponding to the angle of α of −5 degrees represents the relationships between the measured amounts of leaking air from the fourth test samples of the gas sensor 1 and the corresponding measured maximum depths A of the fourth test samples thereof “−10°” corresponding to the angle of α of 10 degrees represents the relationships between the measured amounts of leaking air from the fifth test samples of the gas sensor 1 and the corresponding measured maximum depths A of the fifth test samples thereof.

FIG. 9 clearly demonstrates that, when the maximum depths A of some of the test samples of the gas sensor 1 are equal to or greater than 0.01 mm, the amounts of leaking air from some of the gas sensors 1 are effectively reduced. Particularly, when the maximum depths A of some of the test samples of the gas sensor 1 are equal to or greater than 0.03 mm, the amounts of leaking air from some of the test samples of the gas sensor 1 are more effectively reduced to less than 0.2 milliliters (mL) per minute.

In contrast, when the maximum depths A of some of the test samples of the gas sensor 1 are equal to or lower than 0 mm, in other words, the edge 221 of the inner circumference of the crimped portion 22 of the housing 2 does not dig in the tapered end surface 43b of the metal ring 43, the amounts of leaking air from some of the test samples of the gas sensor 1 increase.

Thus, in the first embodiment, it is preferable that the maximum depth A of the edge 221 of the inner circumference of the crimped portion 22 of the housing 2 digging in the tapered end surface 43b of the metal ring 43 be set to 0 mm and over, more preferably equal to 0.01 mm and over, furthermore preferably equal to 0.03 mm and over.

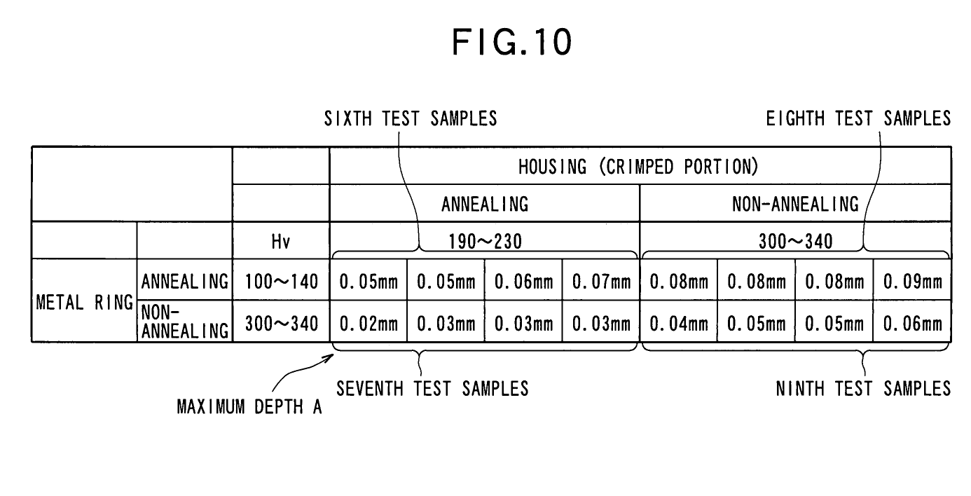

FIG. 10 schematically illustrates relationships between the hardness of each of the housing 2 and the metal ring 43 of each of test samples of the gas sensor 1 according to the first embodiment and the measured maximum depth A of a corresponding one of the test samples of the gas sensor 1.

Specifically, a plurality of first samples of the housing 2 made of stainless steel (SUS 430) and having a hardness value within the range of 190 to 230 Vickers Hardness (HV) were prepared. A plurality of second samples of the housing 2 made of stainless steel (SUS 430) and having a hardness value within the range of 300 to 340 (HV) were prepared. The first samples of the housing 2 were annealed at 850° C., and no anneal process is applied to the second samples thereof.

Similarly, a plurality of first samples of the metal ring 43 made of stainless steel (SUS 430) and having a hardness value within the range of 100 to 140 (HV) were prepared. A plurality of second samples of the metal ring 43 made of stainless steel (SUS 430) and having a hardness value within the range of 300 to 340 (HV) were prepared. The first samples of the metal ring 43 were annealed at 850° C., and no anneal process is applied to the second samples thereof.

Note that the hardness value (HV) of each sample of each of the housing 2 and the metal ring 43 was obtained by;

measuring hardness values at four points on a corresponding one sample using test force F of 4.9 N; and

averaging the measured hardness values to thereby set the averaged value as the hardness value (HV) of the corresponding one sample.

Note that four points of each sample of the housing 2 are located on a part thereof to be crimped as the crimped portion 22.

Specifically, the obtained hardness values (HV) of four samples arbitrarily selected from the plurality of first samples of the housing 2 are within the range of 190 to 230 (HV). The obtained hardness values (HV) of four samples arbitrarily selected from the plurality of second samples of the housing 2 are within the range of 300 to 340 (HV).

The obtained hardness values (HV) of four samples arbitrarily selected from the plurality of first samples of the metal ring 43 are within the range of 100 to 140 (HV). The obtained hardness values (HV) of four samples arbitrarily selected from the plurality of second samples of the metal ring 43 are within the range of 300 to 340 (HV).

Four samples in the first samples of the housing 2 except for the arbitrarily selected samples therein and four samples in the first samples of the metal ring except for the arbitrarily selected samples therein are combined to manufacture sixth test samples of the gas sensor 1.

Four samples in the first samples of the housing 2 except for the arbitrarily selected samples therein and four samples in the second samples of the metal ring except for the arbitrarily selected samples therein are combined to manufacture seventh test samples of the gas sensor 1.

Four samples in the second samples of the housing 2 except for the arbitrarily selected samples therein and four samples in the first samples of the metal ring except for the arbitrarily selected samples therein are combined to manufacture eighth test samples of the gas sensor 1.

Four samples in the second samples of the housing 2 except for the arbitrarily selected samples therein and four samples in the second samples of the metal ring except for the arbitrarily selected samples therein are combined to manufacture ninth test samples of the gas sensor 1.

In forming the crimped portion 22 of each of the sixth to ninth test samples of the gas sensor 1, the load on the crimped portion 22 by the corresponding test sample of the die 5 was set to 1 ton.

Thereafter, the maximum depth A of the edge 221 of the inner circumference of the crimped portion 22 of the housing 2 digging in the tapered end surface 43b of the metal ring 43 of each of the sixth to ninth test samples of the gas sensor 1 was individually measured by, for example, cross-section observation.

FIG. 10 illustrates the measured maximum depths A of the sixth to ninth test samples of the gas sensor 1.

FIG. 10 clearly demonstrates that the maximum depth A of the edge 221 of the inner circumference of the crimped portion 22 of the housing 2 digging in the tapered end surface 43b of the metal ring 43 of each of the sixth to ninth test samples of the gas sensor 1 is set to be equal to or greater than 0.02 mm.

FIG. 10 also demonstrates that the edge 221 of the inner LS circumference of the crimped portion 22 of the housing 2 more easily digs into the tapered end surface 43b of the metal ring 43 when the housing 2 is higher in hardness than the metal ring 43, as compared with when the metal ring 43 is higher in hardness than the housing 2.

Thus, it is preferable that the housing 2 be greater in hardness than the metal ring 43.

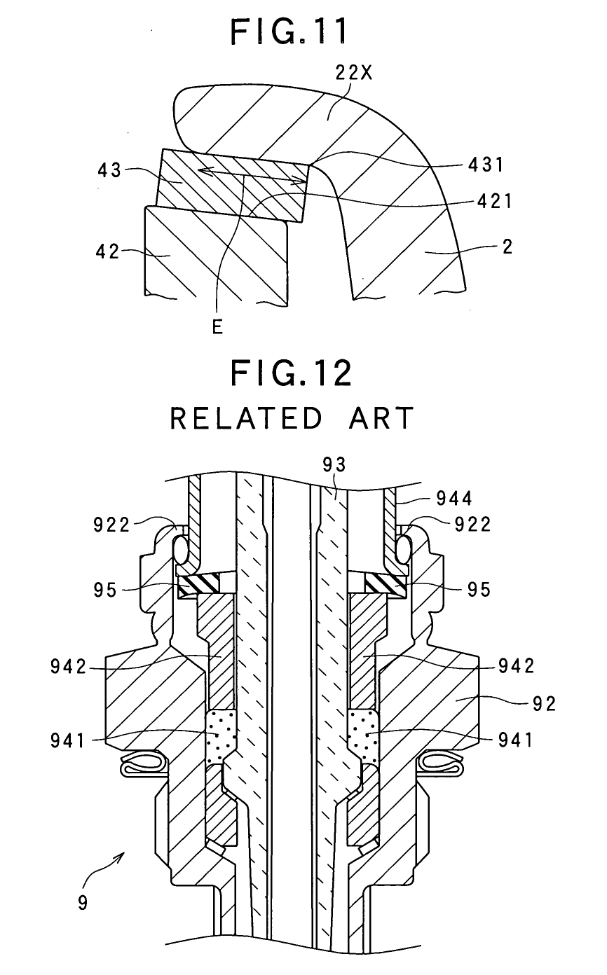

FIG. 11 schematically illustrates the structure of a gas sensor 1C as a comparison example of the gas sensor 1 wherein a crimped portion 22X does not dig in the tapered end surface 43b of the metal ring 43. Like parts between the gas sensors 1 and 1C according to the first embodiment and the comparison example, to which like reference characters are assigned, are omitted or simplified in description.

In the comparison example, a point of application of the load of the crimped portion 22X on the metal ring 43 varies within a part E of the tapered end surface 43b of the metal ring 43; this part is contacted with the crimped portion 22X (see FIG. 11).

Thus, a point of application of the load of the crimped portion 22X on the metal ring 43 may be located at the outer peripheral edge 431 of the tapered end surface 43b of the metal ring 43. In this case, the difference in the amount of thermal expansion between the insulator 42 and each of the metal ring 43 and the crimped portion 22X at the outer periphery edge 431 causes the difference in point of the load between the insulator 42 and each of the metal ring 43 and the crimped portion 22X.

This results in that, in a high-temperature environment, the housing 2 radially expands away from the protect members 42 and 41 due to the difference in linear expansion coefficient between the housing 2 and the protect members 42 and 41. This causes the crimped end 22X of the housing 2 to outwardly move in a radial direction relative to the tubular insulator 42 and the seal member 41. This reduces the pressing force based on the crimped end 22X of the housing 2 to the seal member 41.

In contrast, in the gas sensor 1 according to each of the first to third embodiments, the edge 221 of the inner circumference of the crimped portion 22 digs in the other end surface 43b of the metal ring 43. Thus, a point of application of the load of the crimped portion 22 on the metal ring 43 is stable at the inner circumference side of the metal ring 43 in which the crimped portion 22 digs. In addition, the radius of the edge 221 of the inner circumference of the crimped portion 22 digging in the metal ring 43 is smaller than that of another portion thereof.

Thus, even in a high-temperature environment, the outward movement of the crimped portion 22 of the one open end of the housing 2 and the metal ring 43 at the point of application of the load of the crimped portion 22 is reduced. This makes it possible to limit the reduction in the pressing force applied to the seal member 41 by the crimped portion 22, thereby preventing reduction in the sealability between the housing 2 and the sensor member 3.

The reduction in the pressing force applied to the seal member 41 by the crimped portion 22 of the gas sensor 1 and that in the pressing force applied to the seal member 41 by the crimped portion 22X of the gas sensor 1C were simulated. As the conditions of the simulation, the conditions to be used by the gas sensor 1 were employed.

Specifically, the insulator 42 was made of alumina with the linear expansion coefficient of 7.9×10⁻⁶/° C., and each of the metal ring 42 and the housing 2 was made of stainless steel (SUS 430) with the linear expansion coefficient of 11.7×10⁻⁶/° C. The outer diameter of the metal ring 43 is set to be 13.5 mm (radius is 6.75 mm), and the inner diameter of the metal ring 43 is set to be 9 mm (radius is 4.5 mm).

In the comparison example, a point of application of the load of the crimped portion 22X on the metal ring 43 is located at the outer peripheral edge 431 of the tapered end surface 43b of the metal ring 43. In other words, a point of application of the load of the crimped portion 22X on the metal ring 43 is located at the radius 6.75 mm of the tapered end surface 43b of the metal ring 43.

The amount of expansion of the metal ring 43 at the point of application of the load of the crimped portion 22X on the metal ring 43 during increase in the temperature of 700° C. was calculated as approximately 55 μm. The amount of expansion of the insulator 42 at the point of application of the load of the crimped portion 22X on the metal ring 43 during increase in the temperature of 700° C. was calculated as approximately 37 μm. The difference in thermal expansion between the metal ring 43 and the insulator 42 at the point of application of the load of the crimped portion 22X on the metal ring 43 is 18 μm.

Specifically, the metal ring 43 is outwardly moved relative to the tapered end surface 421 of the insulator 42 by 18 μm. This results in that the pressing force to be applied to the seal member 41 is reduced based on the offset of 18 μm.

In contrast, a point of application of the load of the crimped portion 22 on the metal ring 43 is located at the edge 221 of the inner circumference of the tapered end surface 43b of the metal ring 43. In other words, a point of application of the load of the crimped portion 22 on the metal ring 43 is located at the radius 4.8 mm of the tapered end surface 43b of the metal ring 43.

The amount of expansion of the metal ring 43 at the point of application of the load of the crimped portion 22 on the metal ring 43 during increase in the temperature of 700° C. was calculated as approximately 39 μm. The amount of expansion of the insulator 42 at the point of application of the load of the crimped portion 22 on the metal ring 43 during increase in the temperature of 700° C. was calculated as approximately 27 μm. The difference in thermal expansion between the metal ring 43 and the insulator 42 at the point of application of the load of the crimped portion 22 on the metal ring 43 is 12 μm.

Specifically, it is possible to reduce the difference in thermal expansion between the metal ring 43 and the insulator 42 according to the first embodiment, as compared with that in thermal expansion between the metal ring 43 and the insulator 42 according to the comparison example by approximately 33 percent. This reduces the length of outward shift of the metal ring 43 relative to the tapered end surface 421 of the insulator 43 of the gas sensors 1, 1A, and 1B according to each of the first to third embodiments as compared with the gas sensor 1C according to the comparison example.

Specifically, the simulation can estimate that the structure of the gas sensor 1 sufficiently reduces the reduction in the pressing force applied to the seal member 41 based on the crimped portion.

In each of the first to third embodiments, the other end surface 421 of the tubular insulator 42 is outwardly tapered in its longitudinal direction (axial direction), but the present invention is not limited to the structure. Specifically, the other end surface 421 of the tubular insulator 42 can be parallel to a radial direction of the housing 2, and the other end surface 43b of the metal ring 43 can be parallel to the tapered end surface 421 of the tubular insulator 42.

While there has been described what is at present considered to be the embodiments and their modifications of the present invention, it will be understood that various modifications which are not described yet may be made therein, and it is intended to cover in the appended claims all such modifications as fall within the true spirit and scope of the invention.

What is claimed is:

1. A gas sensor comprising:
a tubular housing having one open end and an inner circumference defining a lengthy opening, the inner circumference having an inward shoulder portion;
a lengthy tubular sensor member having an outer circumference and working to sense at least a component of gas, the outer circumference having an outward shoulder portion, the sensor member being disposed in the lengthy opening such that the outward shoulder portion and the inward shoulder portion are in abutment with each other, the outer circumference of the sensor member and the inner circumference of the housing providing an annular space therebetween, the annular space being disposed between the abutted inward and outward shoulder portions and the one open end of the housing;
a seal member filled in the annular space to be mounted on the abutted inward and outward shoulder portions;
a tubular insulator having a first end surface and a second end surface opposite thereto and installed in the annular space to be mounted at the first end surface thereof on the seal member; and
a ring member having a first end surface and a second end surface opposite thereto and installed in the annular space to be mounted at the first end surface thereof on the second end surface of the tubular insulator,
the one open end of the housing being configured to be inwardly crimped such that an edge of the inner circumference of the inwardly crimped one open end of the housing digs in the second end surface of the ring member to thereby fixedly press the seal member, the insulator, and the ring member to the abutted inward and outward shoulder portions.

2. A gas sensor according to claim 1, wherein the sensor member comprises:
a lengthy sensing element working to sense at least the component of the gas and disposed in the lengthy opening; and
an insulator holder installed in the lengthy opening and surrounding the sensing element, the insulator holder having the outer circumference.

3. A gas sensor according to claim 1, wherein the second end surface of the tubular insulator is tapered toward the inwardly crimped one open end of the housing so that the first and second end surfaces of the ring member are tapered toward the inwardly crimped one open end of the housing, the edge of the inner circumference of the inwardly crimped one open end of the housing digs in an inner periphery of the tapered second end surface of the ring member.

4. A gas sensor according to claim 3, wherein a length between the tapered second end surface of the ring member and a point of the edge of the inner circumference of the inwardly crimped one open end of the housing digging in the inner periphery of the tapered second end surface thereof is set to be equal to or greater than 0.01 mm, the point of the edge being most separated from the tapered end surface of the ring member.

5. A gas sensor according to claim 3, wherein a length between the tapered second end surface of the ring member and a point of the edge of the inner circumference of the inwardly crimped one open end of the housing digging in the inner periphery of the tapered second end surface thereof is set to be equal to or greater than 0.03 mm, the point of the edge being most separated from the tapered end surface of the ring member.

6. A gas sensor according to claim 1, wherein each of the housing and the ring member is metallic, and a hardness value of the inwardly crimped one open end of the housing is higher than that of the ring member.

7. A method of manufacturing a gas sensor, the method comprising:
preparing a tubular housing having one open end and an inner circumference, the inner circumference defining a lengthy opening and having an inward shoulder portion;
preparing a lengthy tubular sensor member having an outer circumference and working to sense at least a component of gas, the outer circumference having an outward shoulder portion;
inserting, from the one open end of the housing, the sensor member in the lengthy opening such that the outward shoulder portion and the inward shoulder portion are in abutment with each other, the outer circumference of the sensor member and the inner circumference of the housing providing an annular space therebetween, the annular space being disposed between the abutted inward and outward shoulder portions and the one open end of the housing;
filling a seal member in the annular space to be mounted on the abutted inward and outward shoulder portions;
installing, in the annular spade, a tubular insulator to be mounted at one end surface thereof on the seal member;
installing, in the annular space, a ring member to be mounted at one end surface thereof on an other end surface of the tubular insulator; and
inwardly crimping the one open end of the housing such that an edge of the inner circumference of the inwardly crimped one open end of the housing digs in an other end surface of the ring member to thereby fixedly press the seal member, the insulator, and the ring member to the abutted inward and outward shoulder portions.

8. A method according to claim 7, wherein the sensor member comprises:
a lengthy sensing element working to sense at least the component of the gas and disposed in the lengthy opening; and
an insulator holder disposed in the lengthy opening and surrounding the sensing element, the insulator holder having the outer circumference.

9. A method according to claim 7, wherein the inwardly crimping includes:
preparing a press die having a die surface, the die surface being composed of an annular fiat surface and an outwardly flared surface radially extending from an outer peripheral part of the annular fiat surface, the outwardly flared surface having a curved shape in an axial cross section of the die surface;
arranging the press die such that the outwardly flared surface is located to be in contact with the one open end of the housing;
moving the press die toward the abutted inward and outward shoulder portions in the length direction of the sensor member to press the one open end of the housing theretoward so as to inwardly bend the one open end of the housing along the outwardly flared surface of the press die, resulting in that the edge of the inner circumference of the inwardly crimped one open end of the housing digs in the other end surface of the ring member.

10. A method according to claim 9, wherein the other end surface of the tubular insulator is tapered toward the inwardly crimped one open end of the housing so that the one and other end surfaces of the ring member are tapered toward the inwardly crimped one open end of the housing, a first angle β representing an angle of the tapered other end surface of the insulator making with respect to a horizontal direction orthogonal to the length direction of the sensor member, a second angle α representing an angle by which the annular flat surface of the die surface is inclined with respect to a horizontal direction orthogonal to the length direction of the sensor member when the press die is arranged such that the outwardly flared surface is located to be in contact with the one open end of the housing, the first angle β being greater than the second angle α.

11. A method according to claim 7, wherein the housing is metallic, and the inwardly crimping includes:
pressing the one open end of the housing toward the abutted inward and outward shoulder portions at ambient temperature such that the edge of the inner circumference of the one open end of the housing is inwardly crimped; and
energizing the inwardly crimped one open end of the housing while the inwardly crimped one open end of the housing is pressed toward the abutted inward and outward shoulder portions so as to buckle the inwardly crimped one open end of the housing, thus allowing the edge of the inner circumference of the inwardly crimped one open end of the housing to dig in the other end surface of the ring member.

12. A method according to claim 11, further comprising:
preparing a press die having a die surface, the die surface being composed of an annular flat surface and an outwardly flared surface radially extending from an outer peripheral part of the annular flat surface, the outwardly flared surface having a curved shape in an axial cross section of the die surface, one of the pressing step and the energizing step using the press die for pressing the one open end of the housing toward the abutted inward and outward shoulder portions.

13. A method according to claim 12, wherein each of the pressing step and the energizing step uses the press die for pressing the one open end of the housing toward the abutted inward and outward shoulder portions.
